(19) United States
(12) Patent Application Publication
(10) Pub. No.: US 2024/0193326 A1
(43) Pub. Date: Jun. 13, 2024

(54) DATA DRIVEN PRE-JOB PLANNING FOR WIRELINE OPERATIONS

(71) Applicant: Schlumberger Technology Corporation, Sugar Land, TX (US)

(72) Inventors: Muhannad Abuhaikal, Cambridge, MA (US); Tianxiang Su, Arlington, MA (US)

(21) Appl. No.: 18/063,198

(22) Filed: Dec. 8, 2022

(51) Int. Cl. G06F 30/27; G06F 30/18

(52) U.S. Cl. CPC G06F 30/27; G06F 30/18

(57) ABSTRACT

Embodiments presented provide for planning operations for wireline operations personnel in hydrocarbon recovery operations. In one embodiment, legacy planning is combined with uncertainty awareness planning to create more efficient wireline operations functions.

### CROSS-REFERENCE TO RELATED APPLICATIONS

None

### FIELD OF THE DISCLOSURE

Aspects of the disclosure relate to conducting efficient wireline operations in hydrocarbon recovery operations. More specifically, aspects of the disclosure relate to methods for pre-job planning in wireline operations to increase efficiency and safety for workers.

### BACKGROUND

Planning of field operations for hydrocarbon recovery operations reduces the overall cost and increases the safety of operations being performed. Often, hydrocarbon recovery operations are conducted in areas that are adjacent to areas where similar operations have previously occurred. This is because of the presence of extensive “fields” that have the hydrocarbon reserves.

Conventional planning operations entail receiving details of the engineering documents and then applying available equipment to achieve the overall goals of the project. Often, the jobs are repetitive, therefore the amount of planning that is required is minimal.

As easy to reach hydrocarbon reserves are exhausted, greater efforts are used to extract the maximum possible hydrocarbons from those reserves. These additional reserves are more difficult to reach and are much more costly to develop. The techniques that are used to have these areas produce hydrocarbons are very different, therefore each wellbore is specifically and individually planned. Development of these reserves is much more cost intensive, raising the overall costs of production for companies and ultimately, to consumers of the hydrocarbons.

There is a need to provide an apparatus as well as methods that easier to operate than conventional apparatus and methods. There is a need to utilize data in a pre-job planning process to enable efficient wireline operations.

There is a further need to provide apparatus and methods that do not have drawbacks, namely costly production attributes and potentially risky operations while using knowledge obtained from previously retained data to allow for efficient pre-job planning.

There is a still further need to increase worker safety with wireline operations compared to conventional operations.

### SUMMARY

So that the manner in which the above recited features of the present disclosure can be understood in detail, a more particular description of the disclosure, briefly summarized below, may be had by reference to embodiments, some of which are illustrated in the drawings. It is to be noted that the drawings illustrate only typical embodiments of this disclosure and are therefore not to be considered limiting of its scope, for the disclosure may admit to other equally effective embodiments without specific recitation. Accordingly, the following summary provides just a few aspects of the description and should not be used to limit the described embodiments to a single concept.

In one example embodiment, a method is disclosed. The method may comprise collecting data from at least one of job parameters to be completed in a wireline operation and a job design to be optimized for the wireline operation and transmitting the data to a hybrid model for processing. The method may also provide for processing the data with the hybrid model producing results, wherein the results include an optimized job design for the wireline operation and at least one of displaying, printing or saving the results to a non-volatile memory.

In another example embodiment, a method may be performed comprising the steps of inputting a first set of data regarding wireline operations job parameters to a hybrid model and inputting a second set of data regarding job designs to be optimized for the wireline operation to the hybrid model, wherein the job designs include at least one piece of equipment and a wire choice. The method may also provide for processing the first set of data and the second set of data with the hybrid model to produce a result, wherein the result includes an optimized job design for the wireline operation and at least one of displaying, printing or saving the result to a non-volatile memory.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the drawings. It is to be noted, however, that the appended drawings illustrate only typical embodiments of this disclosure and are therefore not be considered limiting of its scope, for the disclosure may admit to other equally effective embodiments.

FIG. 1 is a diagram of a hybrid model for pre-job planning in one example embodiment of the disclosure.

FIG. 2 is a graph of two selected features with historical data from previously completed jobs and a newly generated pre-planned job.

FIG. 3 is a graph of inputs, planning and ranked costs for a pre-job wireline planning in one example embodiment of the disclosure.

FIG. 4 is a graph of the completed ranked costs developed in FIG. 3 in one example embodiment of the disclosure.

FIG. 5 is a graph of a model of fidelity in one example embodiment of the disclosure.

FIG. 6 is a graph of friction coefficient uncertainty and weight uncertainty.

FIG. 7 is a graph of friction uncertainty and lockup probability.

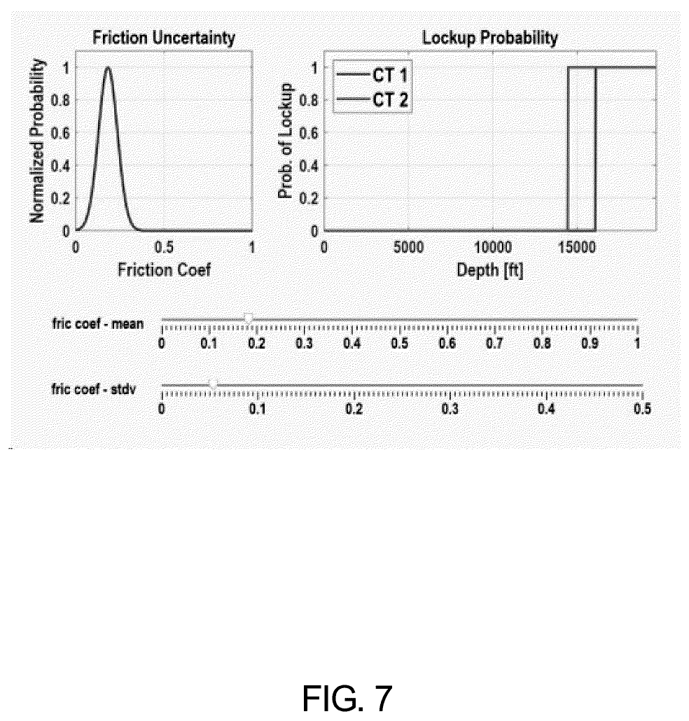

FIG. 8 is a graph of wireline operations in a typical project.

To facilitate understanding, identical reference numerals have been used, where possible, to designate identical elements that are common to the figures (“FIGS”). It is contemplated that elements disclosed in one embodiment may be beneficially utilized on other embodiments without specific recitation.

### DETAILED DESCRIPTION

In the following, reference is made to embodiments of the disclosure. It should be understood, however, that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the claims except where explicitly recited in a claim. Likewise, reference to “the disclosure” shall not be construed as a generalization of inventive subject matter disclosed herein and should not be considered to be an element or limitation of the claims except where explicitly recited in a claim.

Although the terms first, second, third, etc., may be used herein to describe various elements, components, regions, layers and/or sections, these elements, components, regions, layers and/or sections should not be limited by these terms. These terms may be only used to distinguish one element, components, region, layer or section from another region, layer or section. Terms such as “first”, “second” and other numerical terms, when used herein, do not imply a sequence or order unless clearly indicated by the context. Thus, a first element, component, region, layer or section discussed herein could be termed a second element, component, region, layer or section without departing from the teachings of the example embodiments.

When an element or layer is referred to as being “on,” “engaged to,” “connected to,” or “coupled to” another element or layer, it may be directly on, engaged, connected, coupled to the other element or layer, or interleaving elements or layers may be present. In contrast, when an element is referred to as being “directly on,” “directly engaged to,” “directly connected to,” or “directly coupled to” another element or layer, there may be no interleaving elements or layers present. Other words used to describe the relationship between elements should be interpreted in a like fashion. As used herein, the term “and/or” includes any and all combinations of one or more of the associated listed terms.

Some embodiments will now be described with reference to the figures. Like elements in the various figures will be referenced with like numbers for consistency. In the following description, numerous details are set forth to provide an understanding of various embodiments and/or features. It will be understood, however, by those skilled in the art, that some embodiments may be practiced without many of these details, and that numerous variations or modifications from the described embodiments are possible. As used herein, the terms “above” and “below”, “up” and “down”, “upper” and “lower”, “upwardly” and “downwardly”, and other like terms indicating relative positions above or below a given point are used in this description to more clearly describe certain embodiments.

Embodiments of the disclosure relate to pre-job planning for oil field service work. In embodiments, those oil field service operations are wireline operations. Aspects of the disclosure provide for using data obtained from prior wireline projects to aid in planning of future work. In embodiments, features may be selected during the pre-job planning process by planning personnel, and a model is used to allow the planning personnel to see a ranked list of alternatives, developed by the model. The model may use different data in calculations. The data may include historical data in the area, equipment sizes, equipment capacities and other functions. To aid in decision making, personnel may prioritize various factors, such as low economic cost, to develop the best models to use.

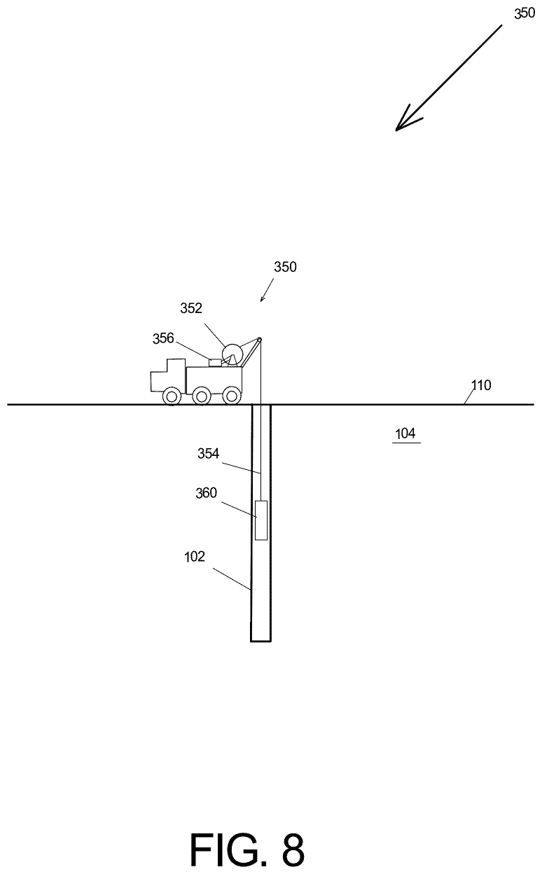

First, by way of illustration, a typical wireline project is illustrated to familiarize the reader with wireline operations. Referring to FIG. 8, wireline operations are performed after the creation of the wellbore. Wireline operations are often accomplished to obtain subsurface petrophysical and geophysical data related to the geological stratum encountered by the wellbore. In these operations, a wireline truck 350 is provided at the surface 110. The wireline truck 350 is provided with a spool 352 that houses a cable 354. The cable 354 may be a single strand or multiple strand cable unit. The cable 354 is configured to allow sensors and equipment to lowered into the wellbore such that the sensors and equipment may conduct required surveys on a formation 104. The lowering action may be accomplished by a motor 356 that is connected to the spool 352. Within the wireline truck 350, an operator may activate and deactivate the motor 356 and control associated gearing to allow the spool 352 to unwind the cable at a desired rate. Sensors may be provided to ascertain the amount of cable that has been unspooled to allow the operator to identify the location of equipment suspended by the cable. The sensors can be located on the wireline truck or adjacent to the wireline truck. The sensors can be attached in a way to determine the tension in the cable, the amount of cable spooled, or other properties of the cable, winch, or the like.

Equipment supported by the cable can be a single instrument package or multiple instrument packages. In the case of multiple instrument packages, such instrument packages may be modular such that different types of packages may be added together according to the needs of the operator. Different types of packages may include, but not be limited to:
Packer systems
Pressure meter testing systems
Nuclear measurement systems
Optical spectrometry systems
Pressure monitoring systems
Resistivity calculation systems
Sonic and ultrasonic tool systems
Borehole seismic tool systems
Nuclear magnetic resonance tool systems
Pressure control systems
Tractor and motion enhancement systems
Power Generation systems
Telemetry and Data recordation systems
Computing systems

Generally, the different modular systems described above may be added together, as needed, to form a logging tool 360 may be called or known as a sonde. The logging tool 360 is lowered into the wellbore to a desired point in the geological stratum and the appropriate system is actuated. The wireline operator may take sensor readings at one point or may take multiple readings while changing the elevation of the logging tool 360. The resulting string of measurements may be called a “log”. Wireline operations may also be used in remediation of a wellbore in order to increase production of hydrocarbons. Such operations, known as remediation or “workovers” may include augmenting existing wellbore parameters.

In the instance of non-vertical wells, wireline operations may be augmented through the use of tractors that allow for the tools to reach more horizontally positions portions of a wellbore. Such horizontal portions of a wellbore may be found, for example, in wells involving fracking operations where a “pay zone” is deposited horizontally parallel to the ground surface. To reach the near horizontal positions of such a wellbore, a tractor that grips the sides of the wellbore may be used to convey instrument packages to the desired position in the wellbore.

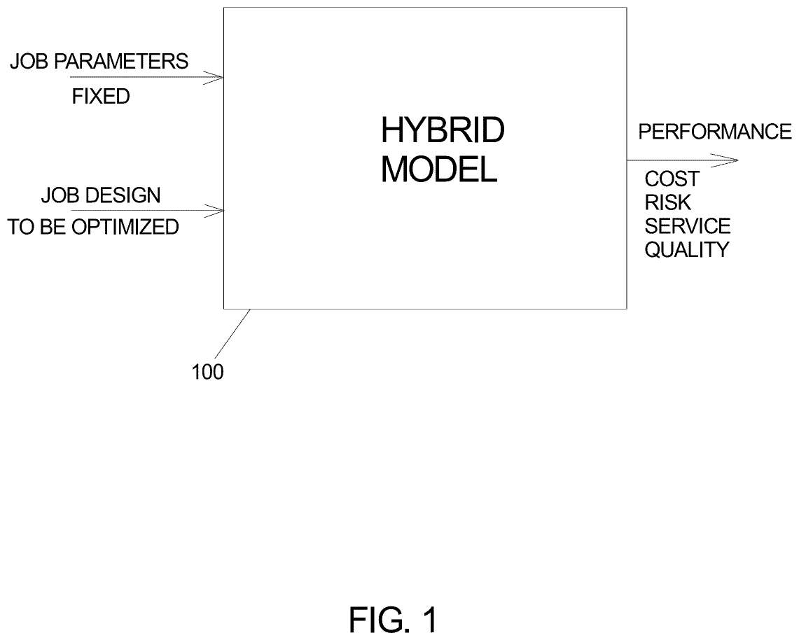

Referring to FIG. 1, a hybrid model 100 is illustrated. The model 100 is used to establish a pre-job plan. The hybrid model 100 allows for job parameters/components and data to be input into the model 100. A hypothetical job design for wireline operations to may also be input into the model 100. The objective of the model 100 is to determine the best available components/planning achievable using historical data. The hybrid model 100 takes these input(s) and processes and may provide job designs proposed by the hybrid model 100 to provide an optimized solution. The output, as illustrated, may rank different factors of the job design, based on different factors. These factors may include, but not be limited to, cost, risk, safety, equipment availability and service quality. The rankings may be from high to low, low to high, similarity to previous projects or other types of rankings. The hybrid model 100 may be personal computer based, web-based and cloud-based as non-limiting embodiments. Results may be displayed on a display, printed or stored in a non-volatile memory. Records of previous jobs may be stored in a computer memory for use in future pre-job optimization.

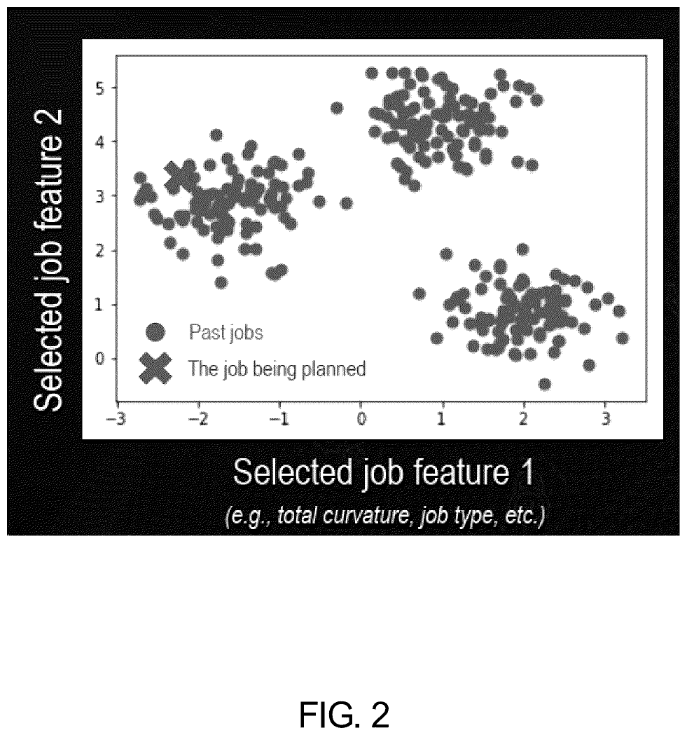

Using the model 100 of FIG. 1, different outputs may be achieved. Referring to FIG. 2, a graph of job activities is described. In the “X” axis, a specific selected feature is illustrated. This first selected job feature may be user defined. The job feature may be any type of data, such as cost, performance, risk, total well depth, well curvature, downhole temperature, downhole pressure, job type, fluid type, other performance features of previous jobs of similar quantities, or combinations thereof. In the “Y” axis, a specified second selected feature is illustrated. This second selected job feature may be user defined, similar to the first specific selected feature. Data from the previous job activities are illustrated as circles in the graph. With the proposed job design, as input to the hybrid model 100, an “X” illustrates the job being planned. Automatic data analysis will show jobs that have been completed that have similar features, allowing job planners to review the materials or allowing the model 100 to select configurations and data within a defined area around the pre-planned job In some instances, it may be desired by planners to minimize the selected feature 2. Feature clustering will indicate the completed jobs that provide that requirement.

As will be understood, selections may also be displayed in other forms, rather than graphically in FIG. 2. In one non-limiting embodiment, a ranked order of jobs may be provided in spreadsheet form for review. Different methods may be used by the model 100 to provide results. In one example embodiment, different clustering, as illustrated, may be used to review results and achieve an optimum output. In a second example embodiment, a correlation model may be used that maps different job features to optimal parameters. In embodiments, certain features may have variability. To handle the variability, statistics are kept on equipment, for help in decision making. Examples of such variables include cable types and age, fluid types, well trajectory, curvature, casing information, surface unit types, job types, tool string configurations, etc.

In other embodiments, different graphs may be used to help planners conceptualize a ranking of a single or multiple features. In some embodiments, a bar graph may be used to graphically represent a single feature.

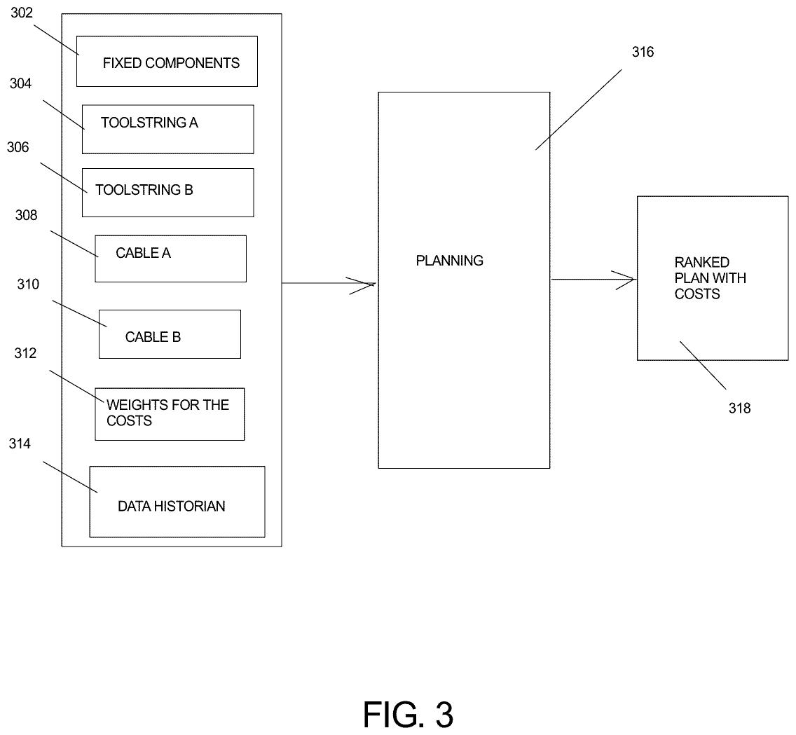

Referring to FIG. 3, a database of different characteristics may be input into a planning process. Illustrative features/characteristics that may be entered include, but not be limited to fixed components 302, tool string A designs 304, tool string B designs 306, values of a cable A 308, values of a cable B 310, weights for different costs 312 and data from a data historian 314. Costs 312 can include economic costs, operational risk, energy cost, operation time, or other cost function for plan optimization. As described above, the data historian 314, may contain a characterization of previous projects that have been completed. In one example embodiment, the data historian 314 may use or retain data from a similar geographic location. In other embodiments, the data that may be retained may include similar depth activities. The illustrative features/characteristics described above are used in planning 316 using the model 100 described above to provide a ranked plan. The pre-job plan may be ranked according to costs 318 in one non-limiting embodiment.

When performing legacy planning in conventional applications, different problems may be encountered. In legacy planning, manual and time-consuming plan comparisons and optimization may be performed. The cost function, in these instances, may be prioritized and may be the objective. In such legacy planning, a data historian is not used, therefore planning does not learn from past failures or excessive costs. The model 100 solves these problems using past data to achieve better results than previously achievable. The model 100 provides a high-fidelity result, optimized for the characteristics chosen, avoiding time consuming tasks.

Embodiments of the present disclosure, are different than legacy planning. In one example embodiment, such as autonomous optimization-based planning, a user may provide a fixed and changeable system set of components. Embodiments may include, for example, different tool string components, different wireline options, etc. that are optimized for use. The software in the model may intelligently select the best combination of changeable components based upon factors deemed important by the planner. For example, a customized cost function balancing different risks and/or energy costs may be provided. Such functions may provide for more efficient optimization than conventional planning apparatus. Planners may automatically obtain domain knowledge and use such domain knowledge in future planning. Such actions can, over time, drive down costs and provide greater efficiency compared to conventional planning.

Other embodiments may also provide for different characterization. In some instances, from historical data, different engineering/geological factors are known. Problematic areas, such as reservoir coefficients of friction or other engineering values may be found. Such problematic areas may be displayed or sorted for the planner, showing average values, median values, deviations, standard deviations and other variability to determine potential risks. Risks may be minimized by processing with the model 100, wherein historical data is used to determine designs that minimize problematic designs. As will be understood, the more data that is present in the data historian, the greater accuracy of ultimately used designs. As an example, it may be found from historical data that a previous project got stuck at a specific depth. Resolution of the issue may have been, for example, to use specific components in the wireline tool. For future jobs, therefore, the model 100 may be programmed to avoid such difficulties, thereby reducing overall costs.

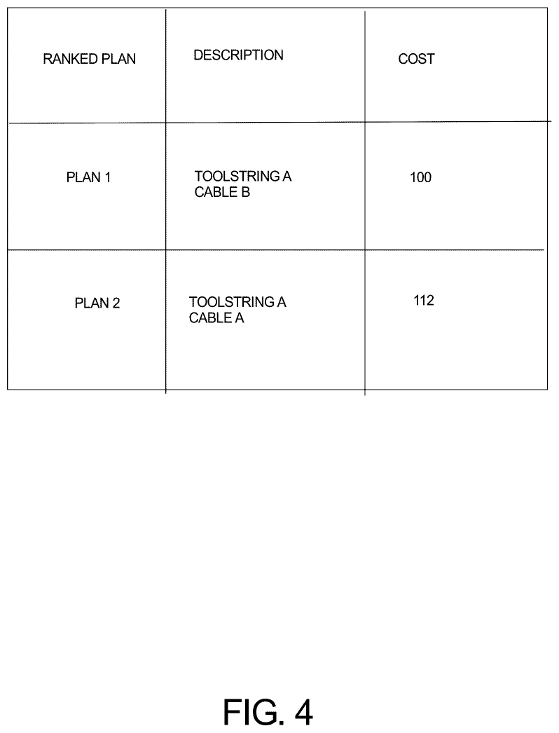

Referring to FIG. 4, an output ranking chart is provided by the model 100. In the output provided, plan 1, is noted as the most cost-effective strategy, wherein a specific tool string A is provided and supported by a specific cable B. Plan 2, which has a tool string A but is supported by a specific cable A, is anticipated to be more expensive, based on historical data, than plan 1. With these answers, planners can optimize the expected costs out of the model 100.

In embodiments, the model 100 may utilize artificial intelligence in making alternative choices as well. One such embodiment may use an artificial neural network. In such embodiments, the model 100 may allow for provision of specific “weights” to different data. Then, selection of components of the overall plan may be chosen using the specific weights attached to the data. In some embodiments, for example, planners may place emphasis on a specific wireline thickness/gauge to be more preferred over other choices. The model 100 may then be used to emphasize these preferred wireline thicknesses compared to others. In embodiments, multiple layers of nodes for decision making may be used. As is known in the art, the addition of multiple layers of nodes would allow for increased accuracy or processing. The model 100 may also be a “learning” model, wherein deviations from expected results are used in an iterative fashion, providing better quality results with each iteration. Such a model 100 may use back propagation algorithms to achieve superior results.

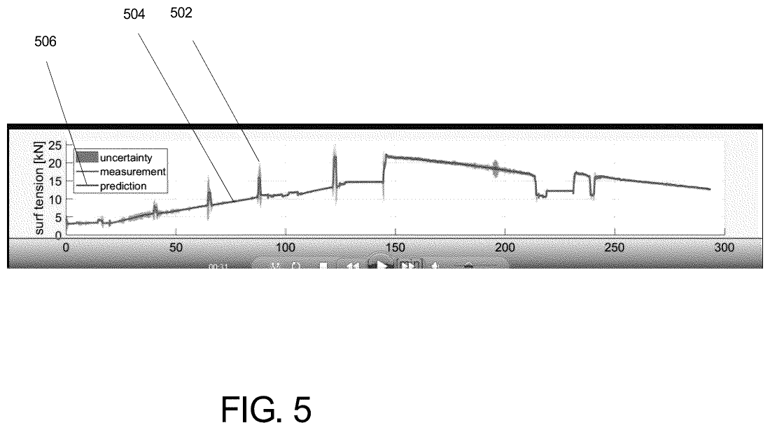

Referring to FIG. 5, embodiments of the model 100 may create selections based upon a fidelity. Fidelity is defined herein as the degree to which a model or simulation reproduces the state or behavior of a real-world object, feature or condition. In other words, fidelity is the degree of similarity between the modeled value and real-world conditions. Values from drilling conditions obtained “while drilling”, for example, may be obtained. The model 100 may then be run in a hypothetical geological stratum and compared to actual values to place emphasis on a fidelity. As illustrated, in a simulation of the model 100, a prediction 506 may be made. Measurements 504 may occur and compared to the prediction 506. Uncertainty 502, may be highlighted as a function of depth, as illustrated in the “X” axis. As provided in FIG. 5, specific elevations produce an uncertainty, therefore provisions in the equipment chosen by the model 100 may address the uncertainty in these areas. Addressing the uncertainty in these areas may include modifying the chosen equipment size, configuration, wireline choice, tractor design or other functions/equipment. In some embodiments, a planner may wish to minimize uncertainty and make sure a project gets performed at a specific deadline. To ensure such a result, equipment may be selected that accounts for the erratic uncertainty, thereby increasing the likelihood of a successful end date.

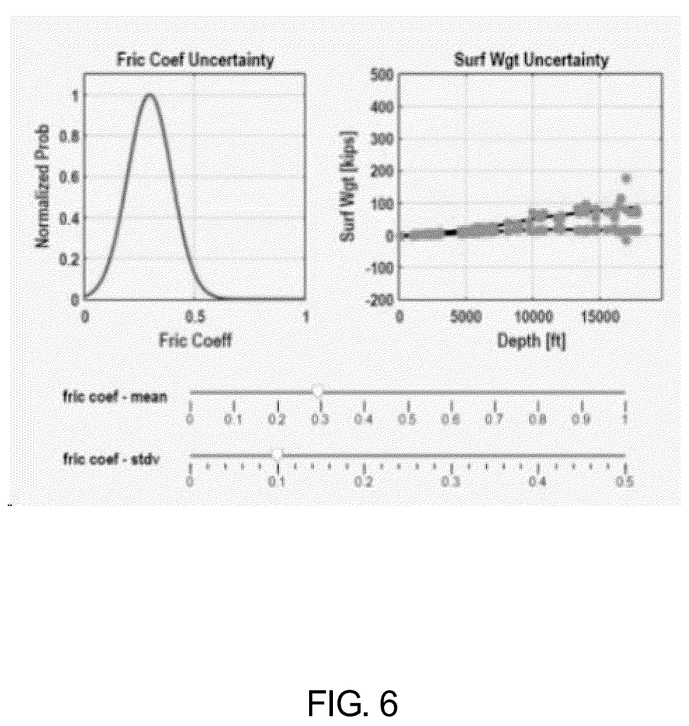

Referring to FIG. 6, a graph of friction coefficient uncertainty and weight uncertainty per depth are provided. Different values, such as friction coefficient mean values and standard deviations are provided. All of these engineering values may be considered, in embodiments, to maximize the overall fidelity of the pre-job plan developed by the model 100. Other values may be similarly analyzed, and the illustrated values are merely examples.

Through the above, data from previous jobs may be used in decision making by the model 100 to arrive at a pre-job configuration that may be used to place emphasis on factors considered important to the job. In one example, a cost function may be used to determine the best result. In other embodiments, a planner may have limited availability of a certain type of equipment. Resultant pre-job planning options from the model may eliminate configurations that use the unavailable materials. The resultant ranked results provide the best alternatives for available materials/components. Unavailable configurations are avoided making the ultimate results usable for the planning process.

As will also be understood, decision making by the model 100 may also account for methods used by field personnel, not just component selection. In one example, it may be found that performing a sonic analysis may be superior to other types of scans. The model 100 may account for the accuracy of needed results, worker field time and other factors in achieving the best pre-job plan.

Example embodiments will now be disclosed. In one example embodiment, a method is disclosed. The method may comprise collecting data from at least one of job parameters to be completed in a wireline operation and a job design to be optimized for the wireline operation and transmitting the data to a hybrid model for processing. The method may also provide for processing the data with the hybrid model producing results, wherein the results include an optimized job design for the wireline operation and at least one of displaying, printing or saving the results to a non-volatile memory.

In another example embodiment, the method may be performed wherein the optimized job design is optimized for at least one of an economic cost, a risk and service quality.

In another example embodiment, the method may be performed wherein the hybrid model comprises artificial intelligence.

In another example embodiment, the method may be performed wherein the hybrid model acts autonomously.

In another example embodiment, the method may be performed wherein the hybrid model further retains historical data on completed wireline projects and uses this historical data to produce the optimized job design.

In another example embodiment, the method may be performed wherein the historical data is stored in a data historian.

In another example embodiment, the method may be performed wherein at least one of tool string designs, wireline types, and fixed components are part of the collected data.

In another example embodiment, the method may be performed wherein the hybrid model ranks the results.

In another example embodiment, the method may be performed wherein the hybrid model is configured to learn from iterative runs.

In another example embodiment, a method may be performed comprising the steps of inputting a first set of data regarding wireline operations job parameters to a hybrid model and inputting a second set of data regarding job designs to be optimized for the wireline operation to the hybrid model, wherein the job designs include at least one piece of equipment and a wire choice. The method may also provide for processing the first set of data and the second set of data with the hybrid model to produce a result, wherein the result includes an optimized job design for the wireline operation and at least one of displaying, printing or saving the result to a non-volatile memory.

In another example embodiment, the method may be performed wherein the optimized job design is optimized for at least one of an economic cost, a risk and service quality.

In another example embodiment, the method may be performed wherein the hybrid model comprises artificial intelligence.

In another example embodiment, the method may be performed wherein the hybrid model acts autonomously.

In another example embodiment, the method may be performed wherein the hybrid model further retains historical data on completed wireline projects and uses the historical data to produce the optimized job design.

In another example embodiment, the method may be performed wherein the historical data is stored in a data historian.

While embodiments have been described herein, those skilled in the art, having benefit of this disclosure, will appreciate that other embodiments are envisioned that do not depart from the inventive scope. Accordingly, the scope of the present claims or any subsequent claims shall not be unduly limited by the description of the embodiments described herein.

What is claimed is:

1. A method, comprising:
collecting data from at least one of job parameters to be completed in a wireline operation and a job design to be optimized for the wireline operation;
transmitting the data to a hybrid model for processing;
processing the data with the hybrid model producing results, wherein the results include an optimized job design for the wireline operation; and
at least one of displaying, printing or saving the results to a non-volatile memory.

2. The method according to claim 1, wherein the optimized job design is optimized for at least one of an economic cost, a risk and service quality.

3. The method according to claim 1, wherein the hybrid model comprises artificial intelligence.

4. The method according to claim 3, wherein the hybrid model acts autonomously.

5. The method according to claim 1, wherein the hybrid model further retains historical data on completed wireline projects and uses this historical data to produce the optimized job design.

6. The method according to claim 5, wherein the historical data is stored in a data historian.

7. The method according to claim 1, wherein at least one of tool string designs, wireline types, and fixed components are part of the collected data.

8. The method according to claim 1, wherein the hybrid model ranks the results.

9. The method according to claim 1, wherein the hybrid model is configured to learn from iterative runs.

10. A method, comprising:
inputting a first set of data regarding wireline operations job parameters to a hybrid model;
inputting a second set of data regarding job designs to be optimized for the wireline operation to the hybrid model, wherein the job designs include at least one piece of equipment and a wire choice;
processing the first set of data and the second set of data with the hybrid model to produce a result, wherein the result includes an optimized job design for the wireline operation; and
at least one of displaying, printing or saving the result to a non-volatile memory.

11. The method according to claim 10, wherein the optimized job design is optimized for at least one of an economic cost, a risk and service quality.

12. The method according to claim 10, wherein the hybrid model comprises artificial intelligence.

13. The method according to claim 12, wherein the hybrid model acts autonomously.

14. The method according to claim 10, wherein the hybrid model further retains historical data on completed wireline projects and uses the historical data to produce the optimized job design.

15. The method according to claim 14, wherein the historical data is stored in a data historian.
